(19) United States
(12) Patent Application Publication
(10) Pub. No.: US 2013/0043592 A1
(43) Pub. Date: Feb. 21, 2013

(54) Methods of Forming a Replacement Gate Comprised of Silicon and a Device Including Same

(71) Applicants: Chang Seo Park, Clifton Park, NY (US); Jin Cho, Palo Alto, CA (US)

(72) Inventors: Chang Seo Park, Clifton Park, NY (US); Jin Cho, Palo Alto, CA (US)

(73) Assignee: GLOBALFOUNDRIES INC., Grand Cayman (KY)

(21) Appl. No.: 13/213,449

(22) Filed: Aug. 19, 2011

(51) Int. Cl. H01L 29/49; H01L 21/28

(52) U.S. Cl. 257/754; 438/592; 257/E21.19; 257/E29.154

(57) ABSTRACT

Disclosed herein are various methods of forming a replacement gate comprised of silicon and various semiconductor devices incorporation such a replacement gate structure. In one example, the method includes removing a sacrificial gate electrode structure to define a gate opening, forming a replacement gate structure in the gate opening, the replacement gate structure including at least one metal layer and a silicon-containing gate structure that is at least partially made of a metal silicide and forming a protective layer above at least a portion of the replacement gate structure.

### BACKGROUND OF THE INVENTION

1. Field of the Invention

Generally, the present disclosure generally relates to the manufacturing of sophisticated semiconductor devices, and, more specifically, to various methods of forming a replacement gate comprised of silicon and various semiconductor devices incorporating such a replacement gate structure.

2. Description of the Related Art

The fabrication of advanced integrated circuits, such as CPU's, storage devices, ASIS's (application specific integrated circuits) and the like, requires the formation of a large number of circuit elements in a given chip area according to a specified circuit layout, wherein field effect transistors (NMOS and PMOS transistors) represent one important type of circuit elements that substantially determine performance of the integrated circuits. During the fabrication of complex integrated circuits using, for instance, MOS technology, millions of transistors, e.g., NMOS transistors and/or PMOS transistors are formed on a substrate including a crystalline semiconductor layer. A field effect transistor, irrespective of whether an NMOS transistor or a PMOS transistor is considered, typically comprises so-called PN junctions that are formed by an interface of highly doped regions, referred to as drain and source regions, with a slightly doped or non-doped region, such as a channel region, disposed between the highly doped regions source/drain regions.

In a field effect transistor, the conductivity of the channel region, i.e., the drive current capability of the conductive channel is controlled by a gate electrode formed adjacent to the channel region and separated therefrom by a thin gate insulation layer. The conductivity of the channel region, upon formation of a conductive channel due to the application of an appropriate control voltage to the gate electrode, depends upon, among other things, the dopant concentration, the mobility of the charge carriers and, for a given extension of the channel region in the transistor width direction, the distance between the source and drain regions, which is also referred to as the channel length of the transistor. Hence, in combination with the capability of rapidly creating a conductive channel below the insulating layer upon application of the control voltage to the gate electrode, the conductivity of the channel region substantially affects the performance of MOS transistors. Thus, since the speed of creating the channel, which depends in part on the conductivity of the gate electrode, and the channel resistivity substantially determine the characteristics of the transistor, the scaling of the channel length, and associated therewith the reduction of channel resistivity and the increase of gate resistivity, are dominant design efforts used to increase the operating speed of the integrated circuits.

For many early device technology generations, the gate electrode structures of most transistor elements has comprised a plurality of silicon-based materials, such as a silicon dioxide and/or silicon oxynitride gate insulation layer, in combination with a polysilicon gate electrode. However, as the channel length of aggressively scaled transistor elements has become increasingly smaller, many newer generation devices employ gate electrode stacks comprising alternative materials in an effort to avoid the short-channel effects which may be associated with the use of traditional silicon-based materials in reduced channel length transistors. For example, in some aggressively scaled transistor elements, which may have channel lengths of on the order of approximately 14-32 nm, gate electrode stacks comprising a so-called high-k dielectric/metal gate (HK/MG) configuration have been shown to provide significantly enhanced operational characteristics over the heretofore more commonly used silicon dioxide/polysilicon (SiO/poly) configurations.

Depending on the specific overall device requirements, several different high-k materials—i.e., materials having a dielectric constant, or k-value, of approximately 10 or greater—have been used with varying degrees of success for the gate insulation layer in a HK/MG gate electrode structure. For example, in some transistor element designs, a high-k gate insulation layer may include tantalum oxide (Ta₂O₅), hafnium oxide (HfO₂), zirconium oxide (ZrO₂), titanium oxide (TiO₂), aluminum oxide (Al₂O₃), hafnium silicates (HfSiOₓ), and the like. Furthermore, one or more non-polysilicon metal gate electrode materials—i.e., a metal gate stack—may be used in HK/MG configurations so as to control the work function of the transistor. These metal gate electrode materials may include, for example, one or more layers of titanium (Ti), titanium nitride (TiN), titanium-aluminum (TiAl), aluminum (Al), aluminum nitride (AlN), tantalum (Ta), tantalum nitride (TaN), tantalum carbide (TaC), tantalum carbonitride (TaCN), tantalum silicon nitride (TaSiN), tantalum silicide (TaSi), and the like.

One well-known processing method that has been used for forming a transistor with a high-k/metal gate structure is the so-called “gate last” or “replacement gate” technique. FIGS. 1A-1D depict one illustrative prior art method for forming an HK/MG replacement gate structure using a gate-last technique. As shown in FIG. 1A, the process includes the formation of a basic transistor structure 100 above a semiconducting substrate 10 in an active area defined by a shallow trench isolation structure 11. At the point of fabrication depicted in FIG. 1A, the device 100 includes a sacrificial gate insulation layer 12, a dummy or sacrificial gate electrode 14, sidewall spacers 16, a layer of insulating material 17 and source/drain regions 18 formed in the substrate 10. The various components and structures of the device 100 may be formed using a variety of different materials and by performing a variety of known techniques. For example, the sacrificial gate insulation layer 12 may be comprised of silicon dioxide, the sacrificial gate electrode 14 may be comprised of polysilicon, the sidewall spacers 16 may be comprised of silicon nitride and the layer of insulating material 17 may be comprised of silicon dioxide. The source/drain regions 18 may be comprised of implanted dopant materials (N-type dopants for NMOS devices and P-type dopant for PMOS devices) that are implanted into the substrate using known masking and ion implantation techniques. Of course, those skilled in the art will recognize that there are other features of the transistor 100 that are not depicted in the drawings for purposes of clarity. For example, so called halo implant regions are not depicted in the drawings as well as various layers or regions of silicon germanium that are typically found in high-performance PMOS transistors. At the point of fabrication depicted in FIG. 1A, the various structures of the device 100 have been formed and a chemical mechanical polishing process (CMP) has been performed to remove any materials above the sacrificial gate electrode 14 (such as a protective cap layer (not shown) comprised of silicon nitride) so that the sacrificial gate electrode 14 may be removed.

As shown in FIG. 1B, one or more etching processes are performed to remove the sacrificial gate electrode 14 and the sacrificial gate insulation layer 12 to thereby define a gate opening 20 where a replacement gate structure will subsequently be formed. A masking layer that is typically used in such etching processes is not depicted for purposes of clarity. Typically, the sacrificial gate insulation layer 12 is removed as part of the replacement gate technique, as depicted herein. However, the sacrificial gate insulation layer 12 may not be removed in all applications.

Next, as shown in FIG. 1 C, various layers of material that will constitute a replacement gate structure 30 are formed in the gate opening 20. In one illustrative example, the replacement gate structure 30 is comprised of a high-k gate insulation layer 30A having a thickness of approximately 2 nm, a work-function adjusting layer 30B comprised of a metal (e.g., a layer of titanium nitride with a thickness of 2-5 nm) and a bulk metal layer 30C (e.g., aluminum). Ultimately, as shown in FIG. 1D, a CMP process is performed to remove excess portions of the gate insulation layer 30A, the work-function adjusting layer 30B and the bulk metal layer 30C positioned outside of the gate opening 20 to define the replacement gate structure 30.

One important aspect of the replacement gate technique involves the formation of a protective dielectric layer (not shown) above the replacement gate structure 30. Such a protective layer acts to protect the replacement gate structure 30 in subsequent processing operations, such as the various process operations performed to form conductive contacts to the source/drain regions 18. Protection of the replacement gate structure 30 is even more important as device dimensions continue to shrink and the use of self-aligned contact formation techniques. One technique that has been employed in the past is to simply form another layer of material above the replacement gate electrode using known deposition techniques. However, such techniques involve performing a number of time-consuming processing operations, and perhaps require hard-masking and patterning which is not feasible with current lithographic alignment capabilities. More recently, efforts have been made to form such a protective layer have included oxidizing, nitriding or fluorinating the metal portions of the replacement gate structure 30. See, for example, US Patent Publication 2011/0062501. However, as the gate length of the device 100 continues to shrink, the proportion of the work function adjusting layer 30B becomes much greater as compared to the other layers that make up the replacement gate structure 30. Oxidation or ntiridation of such a work function adjusting layer 30B comprised of, for example, titanium nitride or tantalum nitride has proven to be difficult. Additionally, there is often a stringent constraint on the allowable temperature of the oxidation or nitridation process, which tends to make the oxidation of metals more difficult. With fluorination it is very difficult to form a sufficiently thick oxide cap layer to protect the underlying replacement gate structure 30.

Another technique that is at least theoretically possible for protecting the underlying metal layers in the gate is perform an etching process to recess the multiple metal layers that are typically present in a replacement gate structure. However, in practice, etching different metal layers typically results in a non-uniform recess as the etch rate of the metal materials in the replacement gate have differing etch rates. This difference in metal etch rates can cause undesirable variations in the gate resistance. Additionally, in attempting to recess the multiple metal layers, the adjacent inter-layer dielectric (ILD), e.g., silicon dioxide or silicon nitride, may be recessed as well do to relatively poor etch selectivity between the metal layers in the gate and the ILD materials. Lastly, even if a protective cover layer of, for example silicon nitride, is formed above the replacement gate structure, such a protection layer is subject to attack in a subsequent etching process performed to form contact openings to underlying source/drain regions if the contact openings are not precisely aligned with the space between adjacent gate electrodes. That is, any mis-alignment during the process of forming contact openings tends to reduce the amount of at least a portion of the protection layer, thereby creating a potential short between the gate electrode and the conductive contact that will eventually be formed in the contact opening.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming a replacement gate comprised of silicon and various semiconductor devices incorporation such a replacement gate structure. In one example, the method includes removing a sacrificial gate electrode structure to define a gate opening, forming a replacement gate structure in the gate opening, the replacement gate structure including at least one metal layer and a silicon-containing gate structure that is at least partially made of a metal silicide and forming a protective layer above at least a portion of the replacement gate structure.

In another illustrative example, the method includes forming removing a sacrificial gate electrode structure to define a gate opening in a layer of insulating material, forming a replacement gate structure in the gate opening, the replacement gate structure having at least one metal layer and a silicon-containing gate structure that is at least partially made of a metal silicide. In this example, the replacement gate structure is made by depositing the at least one metal layer in at least the gate opening, performing a first etching process to remove a portion of the at least one metal layer positioned within the gate opening, after performing the first etching process, depositing a layer of silicon-containing material above the at least one layer of metal and in at least the gate opening, performing a second etching process to remove at least a portion of the layer of silicon-containing material that is positioned within the gate opening to thereby define the silicon-containing gate structure, and converting at least a portion of the silicon-containing gate structure to the metal silicide. In this example, the method concludes with the step of forming a protective layer above at least a portion of the replacement gate structure.

In yet another illustrative example, a device disclosed herein includes a gate insulation layer; a metal layer positioned on the gate insulation layer, the metal layer having a plurality of uppermost surfaces, a silicon-containing gate structure comprised at least partially of a metal silicide, wherein at least a portion of the silicon-containing gate structure is positioned above the metal layer and covers the uppermost surfaces of the metal layer and a protective cap layer positioned above the silicon-containing gate structure.

In yet another example, a device disclosed herein includes a gate insulation layer comprised of a high-k insulating material, a metal layer positioned on the gate insulation layer, the metal layer having a plurality of uppermost surfaces, a silicon-containing gate structure that is made entirely of a metal silicide, wherein a portion of the silicon-containing gate structure is positioned above the metal layer and covers the uppermost surfaces of the metal layer and a protective cap layer positioned above at least the silicon-containing gate structure.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1D depict one illustrative prior art process flow for forming a semiconductor device using a gate last approach; and

FIGS. 2A-2L depict one various illustrative examples of using the methods disclosed herein to form metal oxide regions on the metal layer(s) of a gate structure of a semiconductor device.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

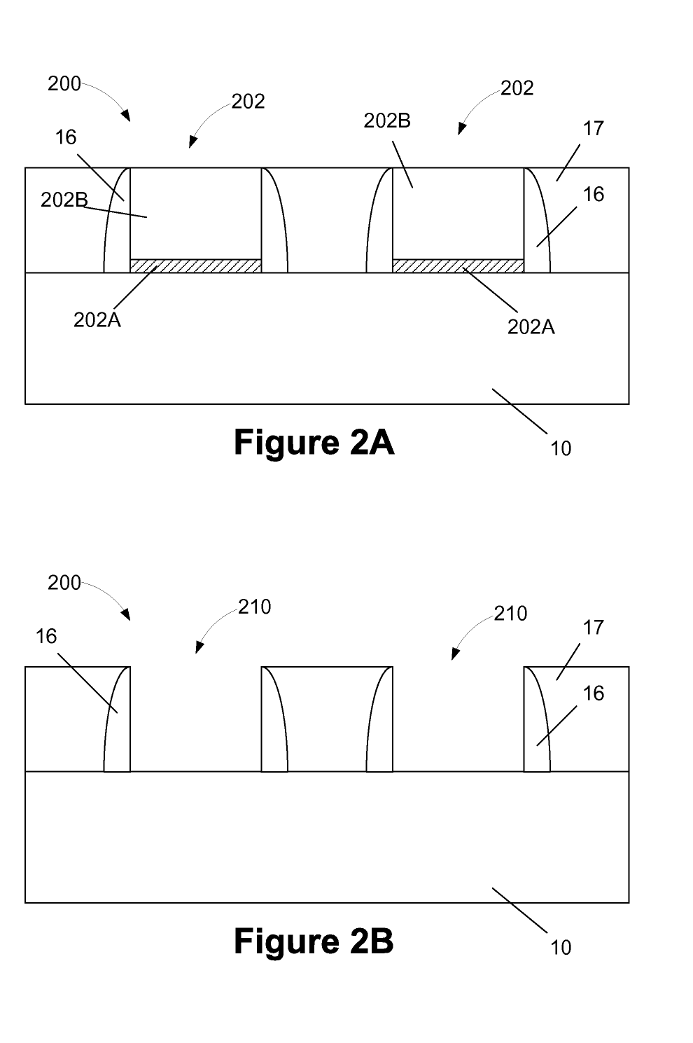

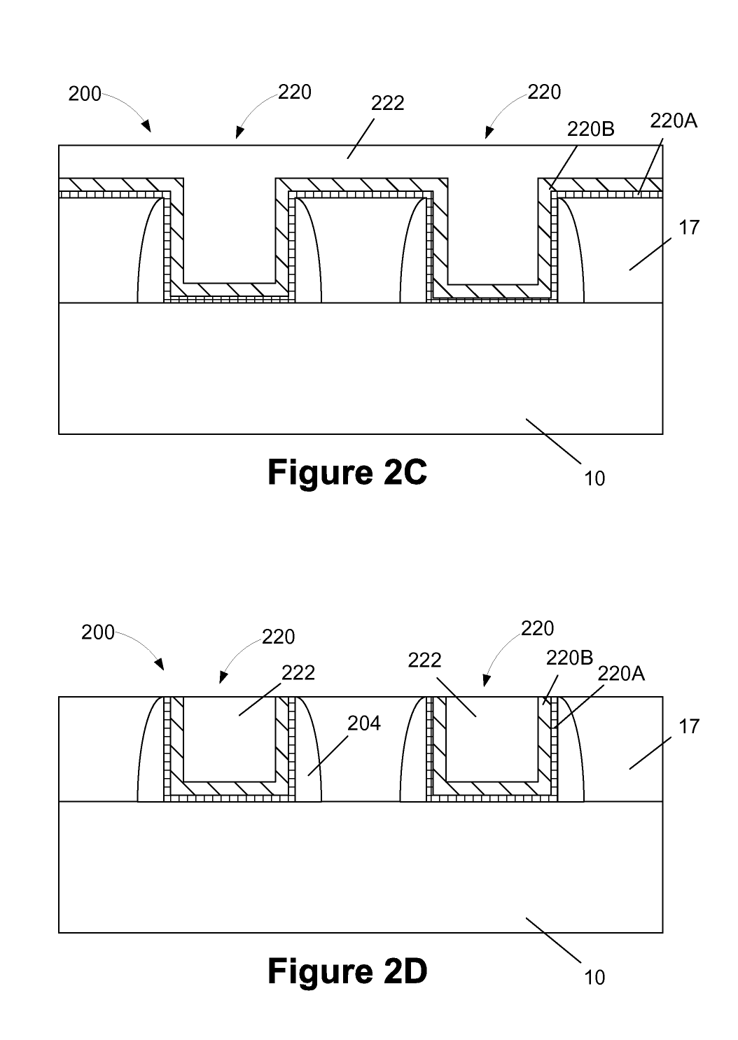

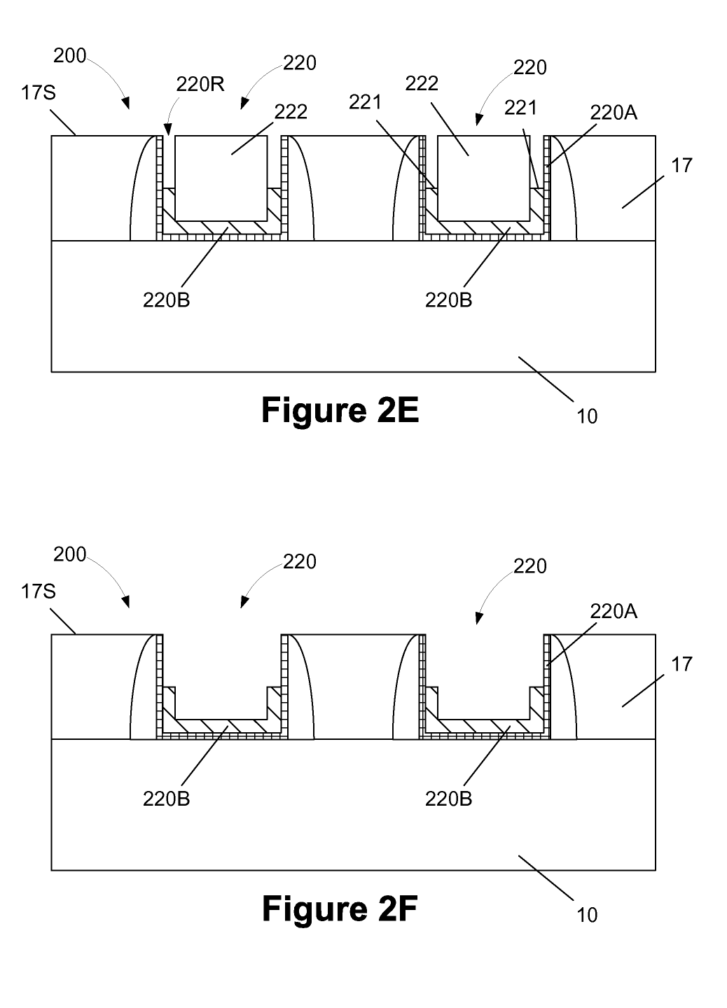

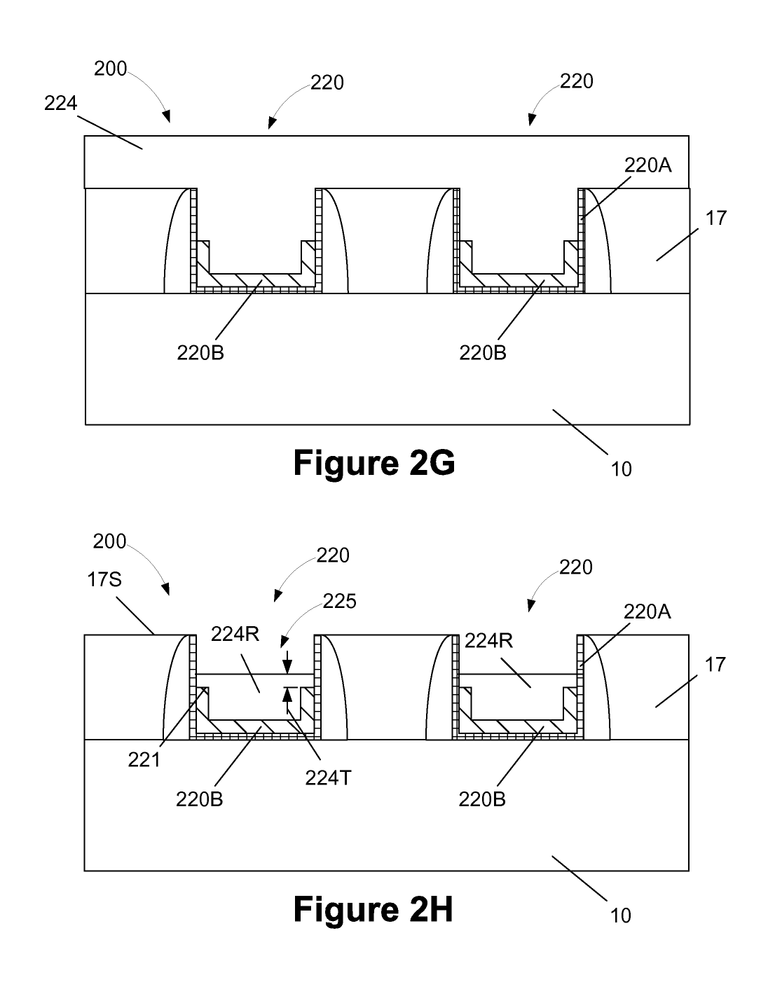

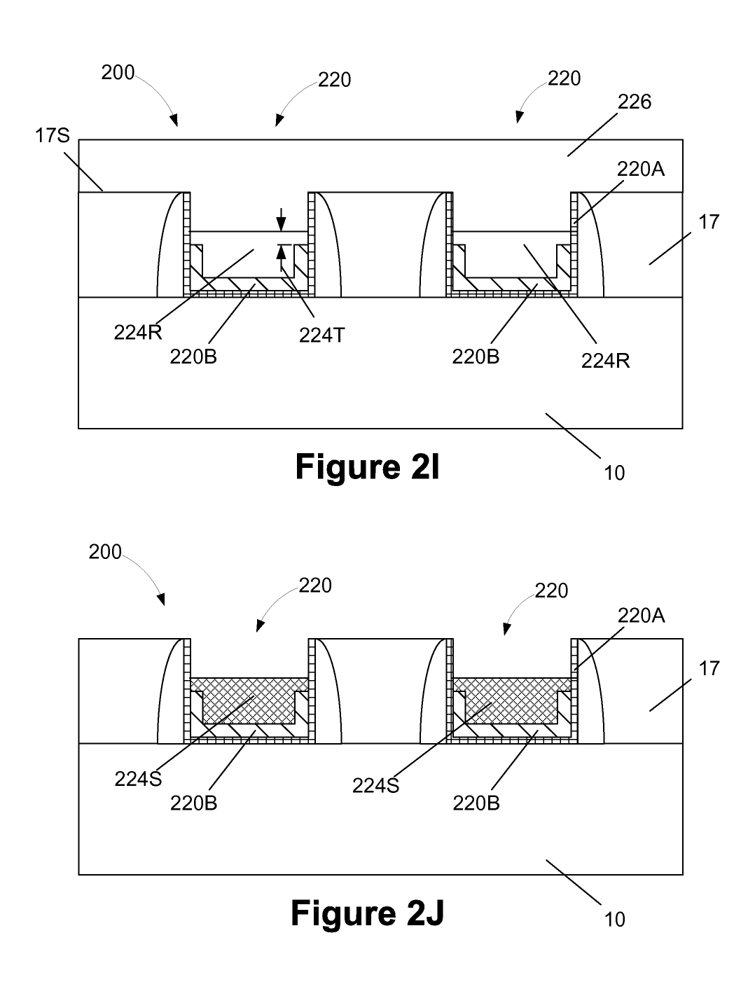

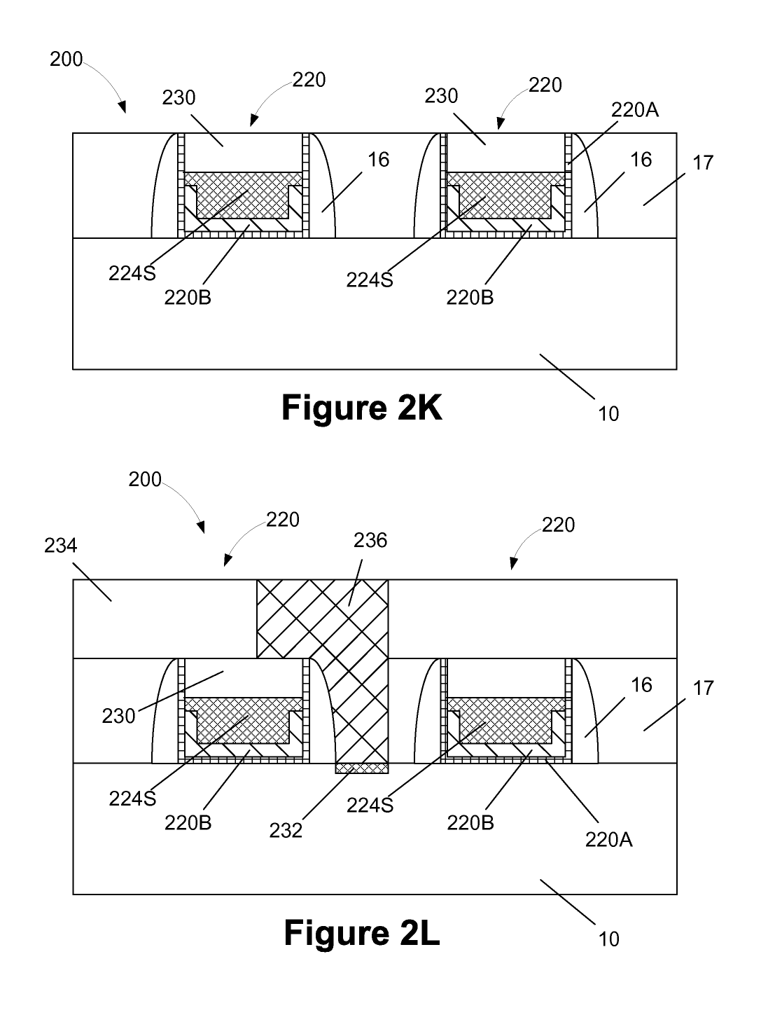

The present disclosure is directed to various methods of forming a replacement gate comprised of silicon and various semiconductor devices incorporating such a replacement gate structure. As will be readily apparent to those skilled in the art upon a complete reading of the present application, the present method is applicable to a variety of technologies, e.g., NMOS, PMOS, CMOS, etc., and is readily applicable to a variety of devices, including, but not limited to, logic devices, memory devices, etc. With reference to FIGS. 2A-2L, various illustrative embodiments of the methods and devices disclosed herein will now be described in more detail.

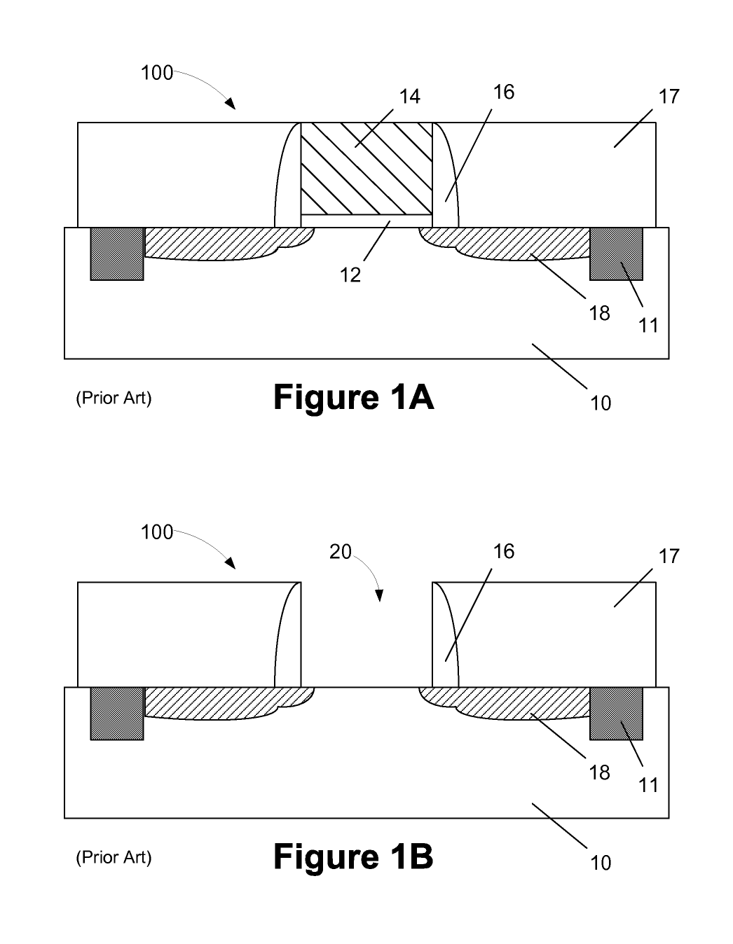

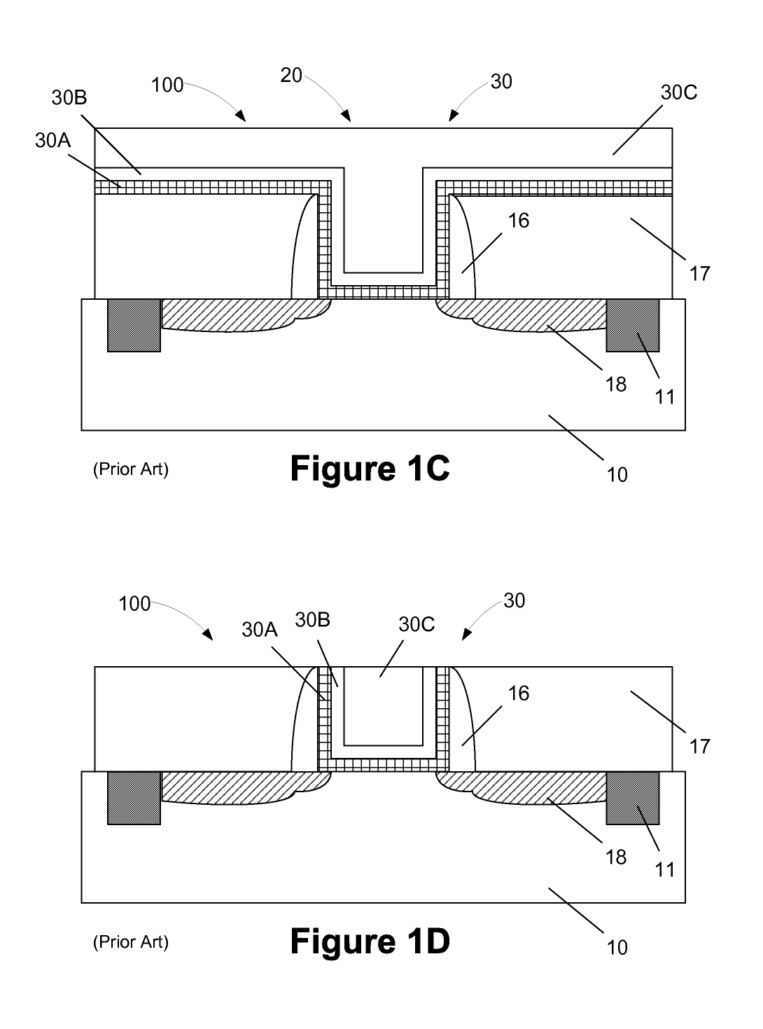

FIG. 2A is a simplified view of an illustrative semiconductor device 200 at an early stage of manufacturing that is formed above a semiconducting substrate 10. At the point of fabrication depicted in FIG. 2A, the device 200 includes a sacrificial gate structure 202 and sidewall spacers 16 positioned in a layer of insulating material 17 formed above a substrate 10. In the depicted example, the sacrificial gate electrode structure 202 includes a sacrificial gate insulation layer 202A and a sacrificial gate electrode 202B. In general, in FIG. 2A, the device 200 is depicted at the point of fabrication that corresponds to that depicted in FIG. 1A for the device 100. Thus, the discussion about illustrative materials and methods of manufacture employed in making the device 100 apply equally to the device 200 up to this point of fabrication. Of course, to the extent that like numbers of various components is used, the previous discussion of those components in connection with the device 100 applies equally as well to the device 200. The substrate 10 may have a variety of configurations, such as the depicted bulk silicon configuration. The substrate 10 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all forms of semiconductor structures. The substrate 10 may also be made of materials other than silicon.

The various components and structures of the device 200 may be formed using a variety of different materials and by performing a variety of known techniques. For example, the sacrificial gate insulation layer 202A may be comprised of silicon dioxide, the sacrificial gate electrode 202B may be comprised of polysilicon, the sidewall spacers 16 may be comprised of silicon nitride and the layer of insulating material 17 may be comprised of silicon dioxide. The sacrificial gate electrode 202B and the sacrificial gate insulation layer 202A may be of any desired thickness or configuration. In one example, the sacrificial gate electrode 202B may have a critical dimension of 20 nm or less. Of course, those skilled in the art will recognize that there are other features of the transistor 200 that are not depicted in the drawings so as not to obscure the present invention. For example, source/drain regions that are typically comprised of implanted dopant materials (N-type dopants for NMOS devices and P-type dopant for PMOS devices) that are implanted into the substrate 10 using known masking and ion implantation techniques are not depicted. Additionally, so called halo implant regions and various layers or regions of silicon germanium that are typically found in high-performance PMOS transistors are not depicted in the drawings. Lastly, the device 200 may be provided with raised or planar source/drain regions. For simplification, the device 200 will be depicted as if planar source/drain regions are formed in the substrate 10. At the point of fabrication depicted in FIG. 2A, the various structures of the device 200 have been formed and a chemical mechanical polishing process (CMP) has been performed to remove any materials above the sacrificial gate electrode 202B (such as a protective cap layer (not shown) comprised of silicon nitride) so that the sacrificial gate structure 202 may be removed.

As shown in FIG. 2B, one or more etching processes are performed to remove the sacrificial gate electrode 202B and the sacrificial gate insulation layer 202A to thereby define a gate opening 210 in the layer of insulating materials where a replacement gate structure will subsequently be formed, as described more fully below. By stating that the gate opening 210 is formed in a layer of insulating material it is intended to cover situations where the gate opening is formed in any combination of insulating materials that may exist at the level for the gate opening 210 whatever form such insulating materials may take. For example, such language should be understood to cover situations where the gate opening 210 is formed between the sidewall spacers 16 and a single layer of insulating material 17, as depicted in the drawings. Such language should also be understood to cover situations where a sidewall spacer might not be present and/or where the layer 17 may be comprised of a plurality of layers of insulating material. A masking layer that is typically used in such etching processes is not depicted for purposes of clarity. Typically, the sacrificial gate insulation layer 202A is removed as part of the replacement gate technique, as depicted herein. However, the sacrificial gate insulation layer 202A may not be removed in all applications.

In general, the present disclosure is directed to forming a novel replacement gate structure 220 in the gate opening 210 and novel methods of forming such a gate structure 220. In the illustrative embodiment depicted herein, the replacement gate structure 220 is comprised of a high-k gate insulation layer 220A and at least one metal layer 220B. Thus, as shown in FIG. 2C, the process involves multiple conformal deposition processes to form the illustrative high-k (k greater than 10) gate insulation layer 220A and the illustrative metal layer 220B. In some examples, the metal layer 220B is a work-function adjusting metal (e.g., a layer of titanium nitride), having a thickness of, for example, 2-5 nm. In other embodiments, one or more additional metal layers may be formed as part of the replacement gate structure 220, although such an additional metal layer(s) is not shown in the drawings. As will be recognized by those skilled in the art after a complete reading of the present application, the insulating materials and the metal layer(s) that are part of the replacement gate structure 220 may be of any desired construction and comprised of any of a variety of different materials. Additionally, the replacement gate structure 220 for a NMOS device may have different material combinations as compared to a replacement gate structure 220 for a PMOS device. Thus, the particular details of construction of replacement gate structure 220, and the manner in which such replacement gate electrode structure 220 is formed, should not be considered a limitation of the present invention unless such limitations are expressly recited in the attached claims. The methods disclosed herein may also be employed replacement gate structures 220 that do not employ a high-k gate insulation layer, although a high-k gate insulation layer will likely be used in most applications.

After the gate insulation layer 220A and the metal layer 220B are formed, the process continues with the formation of a material layer 222 above the metal layer 220B. In one illustrative embodiment, the material layer 222 is an organic planarization layer (OPL) that is formed by a spin coating technique. The layer of material 222 should made of a material that can be easily deposited (or coated) and a material that will readily flow into and fill the remaining portion of the gate opening, as defined by the metal layer 202B, and it should be applied in sufficient thickness such that it accomplishes this goal. The material layer 222 can be readily removed (or stripped) without damaging underlying or adjacent layers of material. The material layer 222 might also be made of certain inorganic materials like silicon nitride or silicon dioxide, but such materials likely might not achieve all of the benefits achieved by using an OPL material.

Next, as shown in FIG. 2D, a CMP process is performed to remove excess portions of the high-k insulating layer 220A, the metal layer 220B and the material layer 222 that are positioned outside of the gate openings 210. Alternatively, a CMP process could be performed to remove the material layer 222, followed by performing one or more etching processes to remove the portions of the high-k insulating layer 220A and the metal layer 220B positioned outside the gate opening 210.

Then, as shown in FIG. 2E, an etching process, either wet or dry, may be performed to etch back the upper portion of the metal layer 220B, as indicated by the recess 220R. This etching process results in removal or a portion of the metal layer 220B from within the gate opening 210 and defined uppermost horizontal surfaces 221 for the metal layer 220B. The depth of the recess 220R relative to the upper surface 17S of the layer of insulating material may vary depending on the particular application and the overall depth of the gate opening 210. In one illustrative embodiment, where the gate opening 210 has a depth of 40-100 nm, the recess 220R may have a depth of 20-50 nm. Although not depicted in the drawings, another etching process could be performed to recess the upper portion of the high-k insulating layer 220A if desired.

Next, as shown in FIG. 2F, the material layer 222 is removed by performing any of a variety of known techniques. For example, depending upon the composition of the material layer 222, it may be stripped using any of a variety of different solvent chemistries.

As shown in FIG. 2G, the next step involves the deposition of a silicon-containing layer or material 224 comprised of, for example, polysilicon or amorphous silicon, etc. to fill the remaining portions of the gate opening 210 the material layer 222 was removed. The silicon-containing layer of material 224 may be either doped or undoped. To the extent the silicon-containing layer of material layer 224 is doped, it is typically doped with an N-type dopant (for NMOS devices) or a P-type dopant (for PMOS devices). The dopants are introduced into the silicon-containing layer of material 224 so that it will be conductive. The silicon-containing layer of material 224 may be formed by performing any of a variety of known processes, such as a chemical vapor deposition (CVD) process, and it should be formed to a sufficient thickness such that it reliably fills the remaining portions of the gate opening 210 and covers the exposed uppermost surfaces 221 of the metal layer 220B.

Next, as shown in FIG. 2H, an etching process is performed to remove the excess portions of the silicon-containing layer of material 224 positioned outside of the gate opening 210 and to remove portions of the silicon-containing layer of material 224 within the gate opening 210 to thereby result in the definition of a recessed silicon-containing gate structure 224R comprised of silicon, having a recess 225 formed thereabove. Alternatively, after the silicon-containing layer of material 224 is deposited, a CMP process may be performed to remove the bulk of the silicon-containing layer of material 224 that is positioned above the surface 17S of the layer of insulating material 17 followed by performing the etching process to define the recessed silicon-containing gate structure 224R. The depth of the recess 225 may vary depending upon the particular application. In one illustrative embodiment, the recess 225 may have a depth (relative to the surface 17S) of approximately 20 nm or less. Additionally, the amount or thickness 224T of the silicon-containing gate structure 224R positioned above uppermost horizontal surfaces 221 of the metal layer 220B may vary depending on the application. In one illustrative embodiment, the thickness 224T may be approximately 5-10 nm.

Then, as shown in FIG. 21, the next step involves converting all or a portion of the silicon-containing gate structure 224R to a metal silicide. In some embodiments described herein, the silicon-containing gate structure 224R may be completely converted to a metal silicide, in other cases, such as when the layer of silicon 224 is doped, the silicon-containing gate structure 224R may be only partially converted to a metal silicide. In the illustrative example depicted in the drawings, the silicon-containing gate structure 224R is depicted as being completely converted to a metal silicide. The metal silicide may be formed using known techniques and any of a variety of different refractory metals may be employed, nickel, platinum, or combinations thereof. To that end, FIG. 21 depicts the deposition of an illustrative layer of refractory metal 226. The layer of refractory metal 226 should be of sufficient thickness such that the desired amount of the silicon-containing gate structure 224R may be converted to a metal silicide. The typical silicidation process involves the depositing the layer of refractory metal 226, performing an anneal process and then performing an etching process to remove unreacted portions of the layer of refractory metal 224. An additional anneal process may be performed in some applications depending upon the metal silicide involved. In the illustrative example depicted herein, the silicidation process results in the formation of a fully silicided gate structure 224S comprised of a nickel-platinum silicide, as shown in FIG. 2J. However, as noted above, in some applications the entirety of the silicon-containing gate structure 224R may not be completely converted to a metal silicide.

Next, as shown in FIG. 2K, a protective cap layer 230 is formed above the illustrative fully silicided silicon-containing gate structure 224S. The protective cap layer 230 may be comprised of a variety of materials, such as silicon nitride, and its thickness may vary depending upon the application, e.g., it may have a thickness of20-50 nm. The protective cap layers 230 shown in FIG. 2K may be formed by depositing a layer of material above the device 200 and thereafter performing a CMP process to remove excess portions of the layer of material.

In one illustrative embodiment, the next step involves forming a metal silicide region 232 on the source/drain region (not depicted in FIG. 2L) of the device 200. The metal silicide region 232 may be same metal silicide as that formed on the silicon containing gate structure 224R, or it may be a different metal silicide. The metal silicide region 232 may be formed using traditional silicidation techniques, such as those previously described above.

In another illustrative example, the metal silicide region may be formed on the source/drain region of the device 200 much earlier in the process flow. For example, such a silicide region may be formed on the source/drain region prior to exposing the sacrificial gate electrode 202B for removal, as depicted in FIG. 2A. Also depicted in FIG. 2L is an illustrative conductive contact 236 that is partially positioned in a layer of insulating material 234. The conductive contact 236 provides electrical connection to the source/drain region of the device 200. The conductive contact 236 may be comprised of a variety of materials, such as tungsten, and it may be formed using techniques well known to those skilled in the art.

One or more of the problems discussed in the background section of the application may be eliminated or at least reduced using the methods and devices disclosed herein. The novel process flow provides for a protective layer that is of sufficient thickness to protect the underlying materials of replacement gate structure 220 from attack during further processing operations. Additionally, the silicided gate structure 224S (fully or partially silicided) provides a more uniform gate structure with more uniform gate resistance as compared to prior art devices. At the point depicted in FIG. 2L, additional processing operations may be performed to complete the formation of the device 200, such as the formation of additional metallization layers (not shown) above the device 200 using known techniques. Of course, the total number of metallization layers may vary depending on the particular device under construction.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
removing a sacrificial gate electrode structure to define a gate opening; and
forming a replacement gate structure in said gate opening, said replacement gate structure comprised of at least one metal layer and a silicon-containing gate structure that is at least partially comprised of a metal silicide; and
forming a protective layer above at least a portion of said replacement gate structure.

2. The method of claim 1, wherein said silicon-containing gate structure is comprised entirely of said metal silicide.

3. The method of claim 1, wherein forming said replacement gate structure in said gate opening comprises depositing a layer of silicon-containing material above said at least one layer of metal and removing portions of said layer of silicon containing material to thereby define said silicon-containing gate structure.

4. The method of claim 3, wherein said step of removing portions of said layer of silicon containing material comprises performing an etching process on said layer of silicon containing material so as to define said silicon-containing gate structure with an upper surface that is recessed relative to an upper surface of a dielectric layer positioned adjacent said gate opening.

5. The method of claim 3, wherein said step of removing portions of said layer of silicon containing material comprises performing a chemical mechanical polishing process to remove at least some of said layer of silicon-containing material positioned outside of said gate opening and thereafter performing an etching process to define said silicon-containing gate structure.

6. The method of claim 3, wherein, prior to depositing said layer of silicon-containing material, said step of forming said replacement gate structure in said gate opening comprises depositing said at least one metal layer at least in said gate opening and thereafter performing an etching process to remove a portion of said at least one metal layer positioned within said gate opening.

7. The method of claim 3, wherein depositing said layer of silicon-containing material comprises depositing a layer of polysilicon or amorphous silicon.

8. The method of claim 3, further comprising depositing a layer of refractory metal on at least said silicon-containing gate structure and performing at least one heating process to form said metal silicide.

9. The method of claim 1, wherein said replacement gate structure further comprises a layer of high-k insulating material.

10. A method, comprising:
removing a sacrificial gate electrode structure to define a gate opening in a layer of insulating material; forming a replacement gate structure in said gate opening, said replacement gate structure comprised of at least one metal layer and a silicon-containing gate structure that is at least partially comprised of a metal silicide by:
depositing said at least one metal layer in at least said gate opening;
performing a first etching process to remove a portion of said at least one metal layer positioned within said gate opening;
after performing said first etching process, depositing a layer of silicon-containing material above said at least one layer of metal and in at least said gate opening;
performing a second etching process to remove at least a portion of said layer of silicon-containing material that is positioned within said gate opening to thereby define said silicon-containing gate structure; and
converting at least a portion of said silicon-containing gate structure to said metal silicide; and
forming a protective layer above at least a portion of said replacement gate structure.

11. The method of claim 10, wherein said silicon-containing gate structure is comprised entirely of said metal silicide and wherein said step of converting at least a portion of said silicon-containing gate structure to said metal silicide comprises converting the entirety of said silicon-containing gate structure to said metal silicide.

12. A device, comprising:
a gate insulation layer;
a metal layer positioned on said gate insulation layer, said metal layer having a plurality of uppermost surfaces;
a silicon-containing gate structure comprised at least partially of a metal silicide, at least a portion of said silicon-containing gate structure positioned above said metal layer and covering said uppermost surfaces of said metal layer; and
a protective cap layer positioned above at least said silicon-containing gate structure.

13. The device of claim 12, wherein said silicon-containing gate structure is comprised entirely of said metal silicide.

14. The device of claim 12, wherein said protective cap layer is comprised of silicon nitride.

15. The device of claim 12, wherein said gate insulation layer is a layer of high-k insulating material.

16. The device of claim 12, further comprising a layer of insulating material that has a top surface that is substantially planar with a top surface of said protective cap layer.

17. The device of claim 16, further comprising at least one sidewall spacer positioned adjacent each of the opposite sides of said silicon-containing gate structure between said silicon-containing gate structure and said layer of insulating material.

18. A device, comprising:
a gate insulation layer comprised of a high-k insulating material;
a metal layer positioned on said gate insulation layer, said metal layer having a plurality of uppermost surfaces;
a silicon-containing gate structure comprised entirely of a metal silicide, at least a portion of said silicon-containing gate structure positioned above said metal layer and covering said uppermost surfaces of said metal layer; and
a protective cap layer positioned above at least said silicon-containing gate structure.
